(19) United States
(12) Patent Application Publication
(10) Pub. No.: US 2026/0251717 A1
(43) Pub. Date: Aug. 27, 2026

(54) SYSTEM STATE-AWARE REAL-TIME DETECTION AND SIDEBAND ORCHESTRATED TARGETED UPDATE

(71) Applicant: DELL PRODUCTS L.P., Round Rock, TX (US)

(72) Inventors: Venkata Rama Krishna Rao Atta, Hyderabad (IN); Ibrahim Sayyed, Georgetown, TX (US); Marcin Nowak, Prosper, TX (US); Amit K. Tiwari, Austin, TX (US)

(21) Appl. No.: 19/063,768

(22) Filed: Feb. 26, 2025

(51) Int. Cl. G01R 31/367

(52) U.S. Cl. CPC G01R 31/367

(57) ABSTRACT

An information handling system that is configured to detect whether it is transitioning to a sleep state. If the information handling system is transitioning to the sleep state, then analyze at least one metric associated with a battery of the information handling system and if the metric exceeds a threshold limit, then perform at least one action associated with the battery based on the metric.

### FIELD OF THE DISCLOSURE

The present disclosure generally relates to information handling systems, and more particularly relates to a system state-aware real-time detection and sideband orchestrated targeted update.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

An information handling system that is configured to detect whether it is transitioning to a sleep state. If the information handling system is transitioning to the sleep state, then analyze at least one metric associated with a battery of the information handling system and if the metric exceeds a threshold limit, then perform at least one action associated with the battery based on the metric.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of an environment for a system state-aware real-time detection and sideband orchestrated targeted update, according to an embodiment of the present disclosure;

FIG. 2 is a flowchart of a method for a system state-aware real-time detection and sideband orchestrated targeted update, according to an embodiment of the present disclosure; and

FIG. 3 is a block diagram of an information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

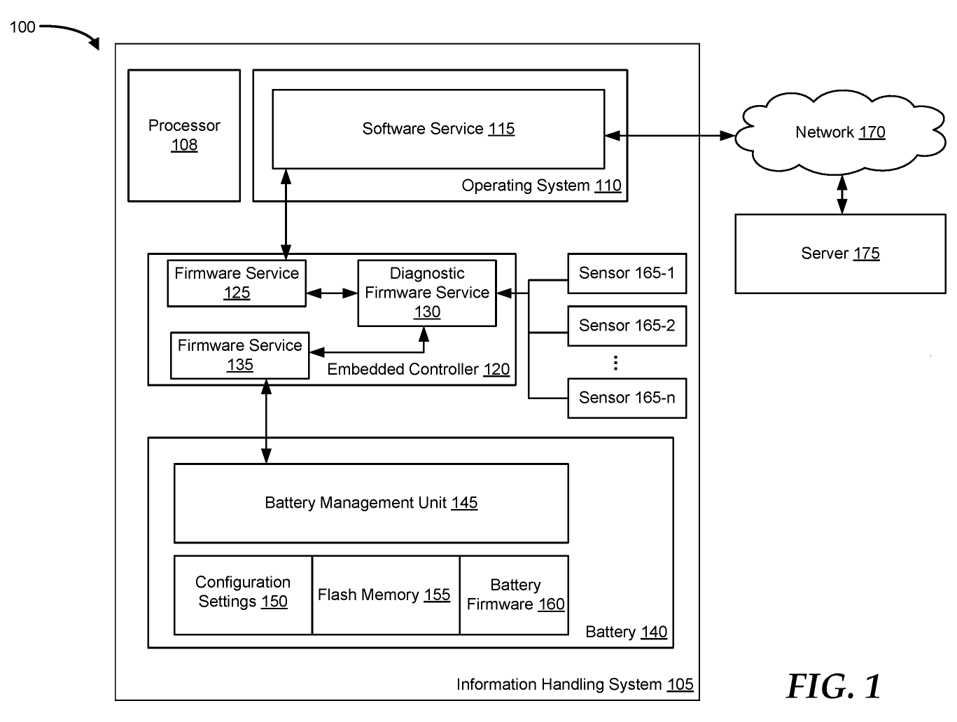

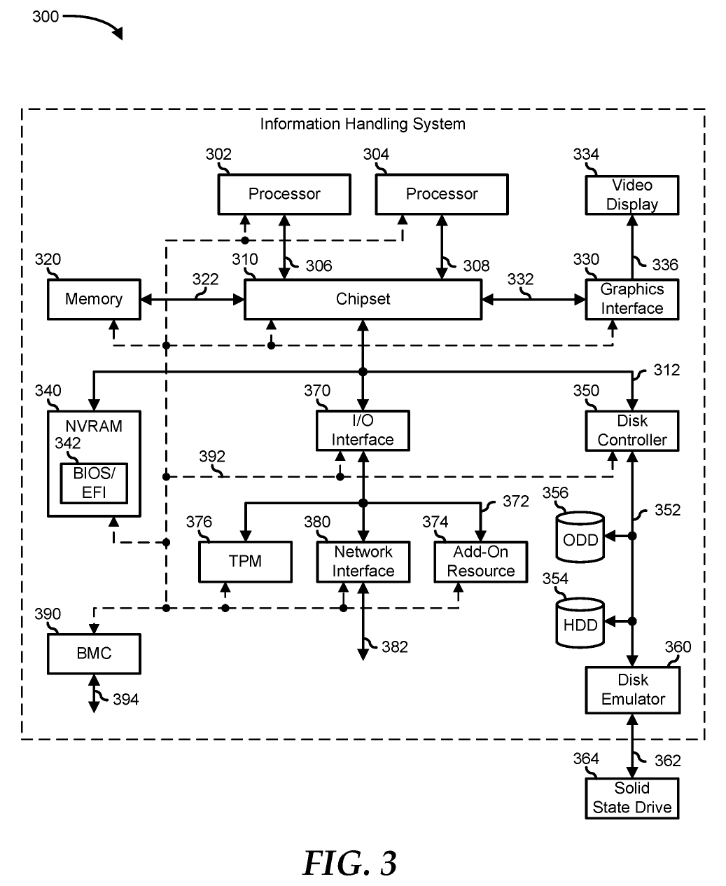

FIG. 1 illustrates a portion of an environment 100 for a system state-aware real-time detection and sideband orchestrated targeted update, according to an embodiment of the present disclosure. Environment 100 includes an information handling system 105, a network 170, and a server 175. Information handling system 105, which is similar to information handling system 300 of FIG. 3, includes a processor 108, an operating system 110, an embedded controller 120, a battery 140, and sensors 165-1 through 165-n. Operating system 110 may be coupled to embedded controller 120 through a sideband channel. Similarly, embedded controller 120 be coupled with a battery 140 through the sideband channel. However, any variety of connections between processor 108, operating system 110, embedded controller 120, and battery 140 are envisioned as falling within the scope of the present disclosure. In addition, connections between components may be omitted for descriptive clarity. The operations described herein as being performed by operating system 110, embedded controller 120, BMU 145, and battery firmware 160 may be performed by a processor, such as processor 108.

In some information handling systems, such as in notebooks, the battery firmware and its configuration are typically immutable, meaning it cannot be updated or modified once deployed. If there is a need to change a BMU firmware, battery firmware, or current configuration settings, the only solution is typically to replace the entire battery. This lack of a mechanism to update the on-chip and configuration on the BMU can lead to false positives in diagnostics and result in unnecessary battery replacements and dispatches. This not only incurs additional costs but also causes inconvenience to users who experience unexpected battery performance issues.

In one scenario, a notebook battery may experience significant drain while the notebook is in a sleep or MODS state. In this scenario, the battery percentage may initially be at 80% before putting the system into sleep mode. However, after several minutes in the sleep mode, the battery charge level drops to 35%. A user runs battery diagnostics to check for any signs of battery degradation or failure, but the diagnostics do not indicate any issues with battery health or degradation. Despite the diagnostics showing no symptoms of failure, the battery discharge rate is significantly higher than an expected or anticipated limit. The battery should maintain a stable charge with minimal discharge during sleep or MODS state. Generally, to remediate this issue, the user may be directed to manually perform a battery calibration cycle, which is generally done without any contextual or configuration information. Accordingly, to address this issue among other concerns, the present disclosure provides a system and method for a system state-aware real-time detection and sideband orchestrated targeted update, such as depicted in environment 100 and a method 200.

Information handling system 105, which is similar to information handling system 300 of FIG. 3, may be a personal computer, a desktop computer system, a laptop computer system, a server computer system, a mobile device, a tablet computing device, a personal digital assistant, a consumer electronic device, an electronic music player, an electronic camera, an electronic video player, a wireless access point, a network storage device, or any other suitable computing device. Information handling system 100 may also be a portable information handling system that may include a laptop, a notebook, a smartphone, a tablet, or a personal digital assistant, among others. Information handling system 105 may support several power management states that correspond to power states defined in the Advanced Configuration and Power Interface (ACPI) specification such as G3, S0, S1-S3, S4, and S5 states.

Processor 108, which is similar to processors 302 and 304 of FIG. 3, may include any system, device, or apparatus operable to interpret and/or execute program instructions and/or process data, and may include, without limitation, a microprocessor, microcontroller, digital signal processor, application specific integrated circuit (ASIC), or any other digital or analog circuitry configured to interpret, and/or execute program instructions and/or process data stored in memory and/or another component of information handling system 105. Processor 108 may be configured to perform instructions associated with operating system 110 and/or other software and/or firmware components of information handling system 105. Operating system 110 is a system software that manages computer hardware and software resources of information handling system 105, such as MICROSOFT WINDOWS, LINUX, or similar. Operating system 110 may also provide common services for computer programs. In one embodiment, operating system 110 may be coupled with embedded controller 120 via a sideband channel, which can be a low-level Inter-Integrated Circuit (I²C) interface, Universal Asynchronous Receiver/Transmitter (UART) interface, or serial peripheral interface (SPI). The sideband channel may be utilized for communication between operating system 110 and embedded controller 120.

In another embodiment, for a Unified Extensible Firmware Interface (UEFI) compliant system that utilizes MICROSOFT WINDOWS for its operating system, communication between the embedded controller, operating system, and applications may be performed according to the ACPI specification. For example, an application may use a WINDOWS Management Instrumentation (WMI) provider that includes ACPI library calls in assembly language to communicate with the embedded controller. In addition, the embedded controller may also send an ACPI system control interrupt (SCI) notification to the operating system. In yet another embodiment, the UEFI-compliant system with MICROSOFT WINDOWS may utilize an embedded controller input/output (EC IO), which generally includes a set of general-purpose input/output (GPIO) pins and/or dedicated interfaces that the embedded controller uses to interact with sensors, power management circuits, fans, keyboards, and other hardware components. The EC IO may be used for system management tasks, such as power sequencing, thermal monitoring, and keyboard scanning among others. EC IO may provide direct control over hardware components via the GPIO pins, analog-to-digital converter (ADC), pulse width modulation (PWM), and other input/output mechanisms. EC IO may also include interfaces, such as I²C, SPI, UART, and System Management Bus (SMBus) for peripheral communication.

Operating system 110 includes a software service 115, which may be any system, device, or apparatus configured to monitor the power management state of information handling system 105 and to communicate with embedded controller 120. For example, software service 115 may send a notification to a firmware service 125 that information handling system 105 has transitioned to a different power management state from a current power management state. In particular, software service 115 may notify firmware service 125 when information handling system 105 transitions from one power management state to another state, such as from a working state (S0) to a sleep state (S1 - S3) or sleep/MODS state through the sideband channel using a device-specific method (DSM). The DSM may be based on the ACPI specification.

Software service 115 may also be configured to receive notification of recalibration of battery 140. Upon receipt of the recalibration notification, software service 115 may check for any latest BMU firmware configuration profile available if any and transmit the configuration profile to embedded controller 120 via the sideband channel. For example, software service 115 may check with server 175 for the BMU firmware configuration profile. The sideband channel may also be utilized for component health and runtime parameters monitoring of battery 140, among others.

Embedded controller 120 includes firmware service 125, a diagnostic firmware service 130, and a firmware service 135. Embedded controller 120, which is similar to BMC 390 of FIG. 3 or firmware service 125 in particular may be configured to track the power management states of information handling system 105, such as when information handling system 105 transitions from a working state (S0) to a sleep state (S3) or MODS state. As such, embedded controller 120 or in particular, firmware service 125 may receive notification from software service 115 of changes in the power management state of information handling system 105, such as when information handling system 105 transitions to a different power management state from a current power management state.

Firmware service 125 may also notify diagnostic firmware service 130 of the transition of the power management states of information handling system 105. Diagnostic firmware service 130 may be system, device, or apparatus configured to run battery diagnostics or self-test to check for potential and/or current functional issues with battery 140 at the hardware level. The battery diagnostics or self-test may be run when information handling system 105 is in the sleep or MODS state, wherein various metrics may be analyzed relative to expected or anticipated levels. Upon detection that one or more of the various metrics are not within the expected or anticipated levels, diagnostic firmware service may notify and direct BMU 145 to perform one or more actions. At this point, embedded controller 120 may switch BMU 145 to a maintenance mode. For example, when a rate of discharge of battery 140 is above the threshold allowed rate, embedded controller 120 may direct BMU 145 to check for potential battery firmware or hardware issues. Diagnostic firmware service 130 may also run the diagnostics or self-check when prompted by an administrator or user.

If no issues are found during the diagnostics or self-check but BMU145 confirms that the rate of discharge of battery 140 is higher than an anticipated limit, embedded controller 120 may keep BMU 145 in the maintenance mode and push dynamically determined system contextual data to BMU 145 using a sideband channel. The contextual data may include information like system ambient temperature, relative humidity, etc. Embedded controller 120 may transmit a command to BMU 145 to recalibrate battery 140 with contextual data configuration so that configuration settings 150 may be updated based on the latest system contextual data and can arrest a faster discharge rate and save battery life. During the configuration operation, embedded controller 120 may communicate with BMU 145, put battery 140 into programming mode, and send a configuration blob and/or firmware image to battery 140. The user or service technician may also try different BMU configuration settings before declaring a failed state and replacing battery 140 with a new battery.

Firmware service 135 may be any system, device, or apparatus configured to communicate with BMU 145. For example, firmware service 135 may also be configured to receive the rate of discharge of battery 140 among other metrics from BMU 145 through the sideband channel and transmit them to diagnostic firmware service 130. In addition, firmware service 135 may include functions and commands to access BMU register data and write into BMU registers to put a BMU chip associated with BMU 145 into programming mode.

When embedded controller 120 detects that information handling system 105 may be transitioning or transitioned into a sleep state and/or receipt of a notification of such transition from operating system 110, embedded controller 120 may capture various metrics, such as the current battery charge level of battery 140, full charge capacity (FCC), and design capacity via BMU 145. When embedded controller 120 receives a sleep exit notification from operating system 110, embedded controller 120 may re-measure the metrics, such as the remaining battery charge level, FCC capacity, and design capacity. If the discharge rate of battery 140 is higher than a threshold limit, embedded controller 120 may call firmware service 125 to evaluate diagnostics results. If discrepancies are found between current measurements and anticipated measurements, embedded controller 120 may notify operating system 110 for a battery recalibration of battery 140.

Upon user confirmation of the battery recalibration and with a power adapter of information handling system 105 connected to an alternating current (AC) power source, such as a wall outlet, embedded controller 120 may generate new configuration settings or data with contextual data collected while information handling system 105 is in the sleep mode. Embedded controller 120 may push the new configuration settings and/or contextual data to BMU 145 over a sideband channel. The new configuration settings may be based on the contextual data, which may include telemetry data from sensors 165-1 through 165-n among others.

Battery 140 includes BMU 145, configuration settings 150, a flash memory 155, and a battery firmware 160. BMU 145 may include a microprocessor, digital signal processor (DSP), ASIC, Field Programmable Gate Array (FPGA), Electrically Erasable Programmable Read-Only Memory (EEPROM), or any combination thereof, or any other device, system, may be configured to manage and/or control operations of battery 140. BMU 145 may utilize firmware, logic, and/or data for controlling the functionality of battery 140. For example, BMU 145 may utilize configuration settings 150 and battery firmware 160 when managing or controlling battery 140.

Configuration settings 150 includes a set of battery configuration settings that are stored in flash memory 155 that is used to manage the operation of battery 140. Flash memory 155 may be an on-chip memory of battery 140. Configuration settings 150 may be updated based on contextual data from at least sensors 165-1 through 165-n and the latest configuration profile stored in server 175. In one example, configuration settings 150 may include one or more threshold values, such as temperature, current, and voltage threshold limits, among others. Configuration settings 150 may be stored as a binary large object (BLOB) in one partition of flash memory 155. Configuration settings 150 may include a manifest schema that can be used on how to interpret the information or data associated with configuration settings 150. The contextual data may include information or telemetry data associated with the system state and history of information handling system 105. For example, the contextual data may include information on whether information handling system 105 experienced an impact event, elevated temperature, change in hardware configuration, etc. Flash memory 155 may be an erasable programmable read-only memory of battery 140 that is configured to store configuration settings 150 in one partition and battery firmware 160 in another partition. Battery firmware 160 may include code executable by BMU 145. The contextual data may also be stored in flash memory 155.

Sensors 165 -1 through 165-n may include a current sensor, a voltage sensor, and a temperature sensor, among others. The current sensor may represent a shunt resistor, or other current sensing element, over which a voltage that is directly proportional to the current flowing through the main power circuit is measured. The voltage sensor may enable voltage measurement of individual battery cells, or measurement of an aggregate voltage for the battery including all battery cells operating together. One or more temperature sensors may be located in proximity to the battery cells to provide accurate indications of the temperature at different locations within battery 140. Information and/or data from sensors 165-1 through 165-n among others may provide contextual information to embedded controller 120 regarding the current state of battery 140.

Network 170 may use any one or more of a variety of networks or another type of communication connection as known to those skilled in the art. The communication connection may be a network connection, bus, and/or another type of data link, such as a hardwire connection, a network cable, wireless or Wi-Fi^{®} protocols, or other connections known in the art. Network 170 may be implemented as or maybe a part of, a storage area network (SAN), a personal area network (PAN), a local area network (LAN), a metropolitan area network (MAN), a wide area network (WAN), a wireless local area network (WLAN), a virtual private network (VPN), an intranet, the Internet, or any other appropriate architecture or system that facilitates the communication of signals, data and/or messages. Network 170 may transmit data using any storage and/or communication protocol, including without limitation, Fibre Channel, Frame Relay, Asynchronous Transfer Mode (ATM), Internet Protocol (IP), other packet-based protocol, small computer system interface (SCSI), Internet SCSI (iSCSI), Serial Attached SCSI (SAS), or any other transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 170 and its various components may be implemented using hardware, software, or any combination thereof. These components may be configured to facilitate communication between information handling system 105 and server 175, among others.

Server 175 may be configured to store BMU firmware configuration profiles of one or more battery types. These configuration profiles may be downloaded by an information handling system, such as information handling system 105. In addition, these configuration profiles may be maintained by an original equipment manufacturer (OEM) of battery 140.

Those of ordinary skill in the art will appreciate that the configuration, hardware, and/or software components of environment 100 may vary. For example, the illustrative components within environment 100 are not intended to be exhaustive but rather are representative to highlight components that can be utilized to implement aspects of the present disclosure. For example, other devices and/or components may be used in addition to or in place of the devices/components depicted. The depicted example does not convey or imply any architectural or other limitations with respect to the presently described embodiments and/or the general disclosure. In the discussion of the figures, reference may also be made to components illustrated in other figures for continuity of the description.

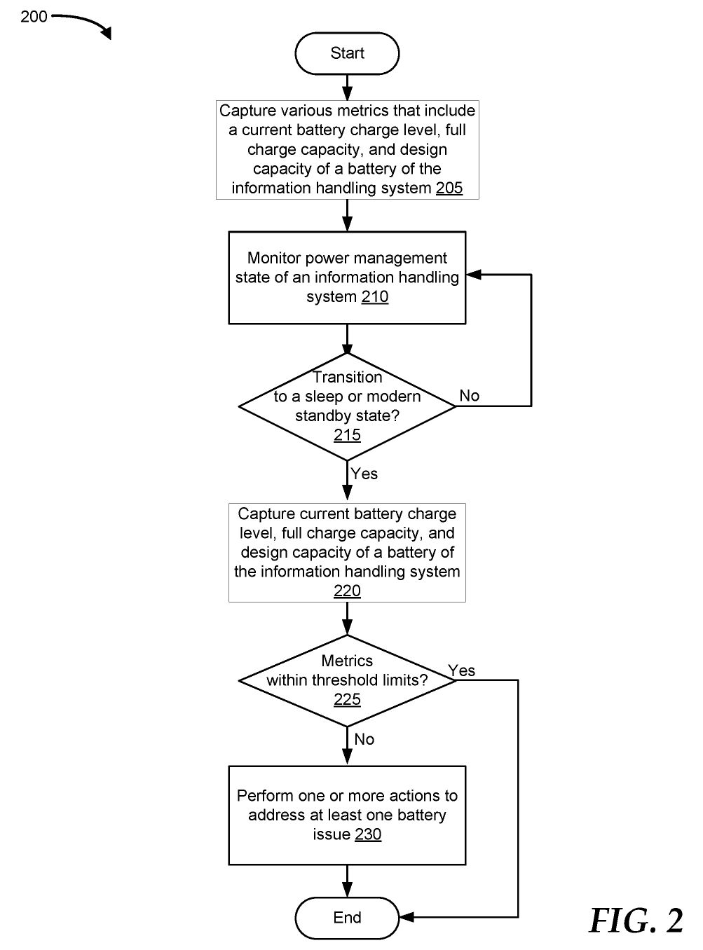

FIG. 2 illustrates a portion of a flowchart of method 200 for system state-aware real-time detection and sideband orchestrated targeted update, according to an embodiment of the present disclosure. Method 200 may be utilized for a sideband firmware inferred intelligent monitoring, evaluation, and targeted action to fix battery issues. Method 200 may be performed by any suitable component of environment 100 of FIG. 1 including, but not limited to, operating system 110, embedded controller 120, and battery 140. While embodiments of the present disclosure are described in terms of the components of environment 100 of FIG. 1, it should be recognized that other components may be utilized to perform the described method.

One of skill in the art will appreciate that this flowchart explains a typical example, which can be extended to applications or services in practice. In an example, method 200 may be performed by any suitable component including, but not limited to, operating system 110, embedded controller 120, and battery 140 of FIG. 1. However, while embodiments of the present disclosure are described in terms of the components of environment 100 of FIG. 1, it should be recognized that other systems may be utilized to perform the described method. In addition, it will be readily appreciated that not every method step set forth in this flowchart is always necessary and that certain steps of the methods may be combined, performed simultaneously, in a different order, or perhaps omitted, without varying from the scope of the disclosure.

Method 200 typically starts with a block 205 where an embedded controller may capture various metrics of a battery of an information handling system. The metrics captured may include a current battery charge level, full charge capacity, design capacity, rate of battery discharge, etc. The method may proceed to a block 210 where the embedded controller may monitor the power management state of the information handling system. The method may proceed to a decision block 215 where the embedded controller may determine whether it detects a transition of a current power management state of the information handling system to a sleep or MODS state. If the embedded controller detects that the information handling system is transitioning to a sleep or MODS state, then the “YES” branch is taken, and the method may proceed to a block 220. If the embedded controller does not detect that the information handling is transitioning to the sleep or MODS state, then the “NO” branch is taken, and the method may proceed to block 210.

At block 220, the embedded controller may capture and analyze various current metrics of the battery from one or more sensors and/or other sources, such as a BMU. The current metrics may include battery charge level, full charge capacity, and design capacity of the information handling system. The embedded controller may analyze the current metrics, such as to determine whether the current metrics exceed or are within threshold limits. The embedded controller may also compare the current metrics from the metrics collected at block 205. For example, the embedded controller may determine whether deltas between the current metrics and the previous metrics are within anticipated or threshold levels. The method may proceed to a decision block 225 where the embedded controller may determine whether the current metrics are within the threshold limits. If the metrics are within the anticipated or threshold limits, then the “YES” branch is taken, and the method ends. If the metrics are not within the anticipated or threshold limits, then the “NO” branch is taken, and the method proceeds to block 230.

At block 230, the embedded controller may determine one or more issues associated with the battery based on the current metrics and/or associated threshold limits. Examples of battery issues include draining quickly, short life span, failing to charge, etc. Based on the determined issue, the embedded controller may direct the BMU to perform one or more actions based on at least one issue determined based on the current metrics and/or associated threshold limits. For example, the BMU may perform diagnostics or self-test, recalibrate the battery using contextual data, reset power rails, update battery configuration settings similar to configuration settings 150 of FIG. 1, and update the battery firmware, among others.

FIG. 3 illustrates an embodiment of an information handling system 300 including processors 302 and 304, a chipset 310, a memory 320, a graphics adapter 330 connected to a video display 334, a non-volatile RAM (NVRAM) 340 that includes a basic input and output system/extensible firmware interface (BIOS/EFI) module 342, a disk controller 350, a hard disk drive (HDD) 354, an optical disk drive (ODD) 356, a disk emulator 360 connected to a solid-state drive (SSD) 364, an I/O interface 370 connected to an add-on resource 374 and a trusted platform module (TPM) 376, a network interface 380, and a BMC 390. Processor 302 is connected to chipset 310 via processor interface 306, and processor 304 is connected to the chipset via processor interface 308. In a particular embodiment, processors 302 and 304 are connected together via a high-capacity coherent fabric, such as a HyperTransport link, a QuickPath Interconnect, or the like. Chipset 310 represents an integrated circuit or group of integrated circuits that manage the data flow between processors 302 and 304 and the other elements of information handling system 300. In a particular embodiment, chipset 310 represents a pair of integrated circuits, such as a northbridge component and a southbridge component. In another embodiment, some or all of the functions and features of chipset 310 are integrated with one or more of processors 302 and 304.

Memory 320 is connected to chipset 310 via a memory interface 322. An example of memory interface 322 includes a DDR memory channel and memory 320 represents one or more DDR DIMMs. In a particular embodiment, memory interface 322 represents two or more DDR channels. In another embodiment, one or more of processors 302 and 304 includes a memory interface that provides a dedicated memory for the processors. A DDR channel and the connected DDR DIMMs can be in accordance with a particular DDR standard, such as a DDR3 standard, a DDR4 standard, a DDR5 standard, or the like.

Memory 320 may further represent various combinations of memory types, such as Dynamic Random Access Memory (DRAM) DIMMs, Static Random Access Memory (SRAM) DIMMs, non-volatile DIMMs (NV-DIMMs), storage class memory devices, Read-Only Memory (ROM) devices, or the like. Graphics adapter 330 is connected to chipset 310 via a graphics interface 332 and provides a video display output 336 to a video display 334. An example of a graphics interface 332 includes a PCIe interface and graphics adapter 330 can include a four-lane (x4) PCIe adapter, an eight-lane (x8) PCIe adapter, a 16-lane (x16) PCIe adapter, or another configuration, as needed or desired. In a particular embodiment, graphics adapter 330 is provided down on a PCB. Video display output 336 can include a Digital Video Interface (DVI), a High-Definition Multimedia Interface (HDMI), a DisplayPort interface, or the like, and video display 334 can include a monitor, a smart television, an embedded display such as a laptop computer display, or the like.

NVRAM 340, disk controller 350, and I/O interface 370 are connected to chipset 310 via an I/O channel 312. An example of I/O channel 312 includes one or more point-to-point PCIe links between chipset 310 and each of NVRAM 340, disk controller 350, and I/O interface 370. Chipset 310 can also include one or more other I/O interfaces, including a PCIe interface, an Industry Standard Architecture (ISA) interface, a Small Computer Serial Interface (SCSI) interface, an Inter-Integrated Circuit (I²C) interface, a System Packet Interface, a Universal Serial Bus (USB), another interface, or a combination thereof. NVRAM 340 includes BIOS/EFI module 342 that stores machine-executable code (BIOS/EFI code) that operates to detect the resources of information handling system 300, to provide drivers for the resources, to initialize the resources, and to provide common access mechanisms for the resources. The functions and features of BIOS/EFI module 342 will be further described below.

Disk controller 350 includes a disk interface 352 that connects the disc controller to a hard disk drive (HDD) 354, to ODD 356, and to disk emulator 360. An example of disk interface 352 includes an Integrated Drive Electronics (IDE) interface, an Advanced Technology Attachment (ATA) such as a parallel ATA (PATA) interface or a SATA interface, a SCSI interface, a USB interface, a proprietary interface, or a combination thereof. Disk emulator 360 permits SSD 364 to be connected to information handling system 300 via an external interface 362. An example of external interface 362 includes a USB interface, an institute of electrical and electronics engineers (IEEE) 1394 (Firewire) interface, a proprietary interface, or a combination thereof. Alternatively, SSD 364 can be disposed within information handling system 300.

I/O interface 370 includes a peripheral interface 372 that connects the I/O interface to add-on resource 374, to TPM 376, and to network interface 380. Peripheral interface 372 can be the same type of interface as I/O channel 312 or can be a different type of interface. As such, I/O interface 370 extends the capacity of I/O channel 312 when peripheral interface 372 and the I/O channel are of the same type, and the I/O interface translates information from a format suitable to the I/O channel to a format suitable to the peripheral interface 372 when they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board, or add-in card disposed within information handling system 300, a device that is external to the information handling system, or a combination thereof.

Network interface 380 represents a network communication device disposed within information handling system 300, on a main circuit board of the information handling system, integrated onto another component such as chipset 310, in another suitable location, or a combination thereof. Network interface 380 includes a network channel 382 that provides an interface to devices that are external to information handling system 300. In a particular embodiment, network channel 382 is of a different type than peripheral interface 372 and network interface 380 translates information from a format suitable to the peripheral channel to a format suitable to external devices.

In a particular embodiment, network interface 380 includes a NIC or host bus adapter (HBA), and an example of network channel 382 includes an InfiniBand channel, a Fibre Channel, a Gigabit Ethernet channel, a proprietary channel architecture, or a combination thereof. In another embodiment, network interface 380 includes a wireless communication interface, and network channel 382 includes a Wi-Fi channel, a near-field communication (NFC) channel, a Bluetooth^{®} or Bluetooth-Low-Energy (BLE) channel, a cellular based interface such as a Global System for Mobile (GSM) interface, a Code-Division Multiple Access (CDMA) interface, a Universal Mobile Telecommunications System (UMTS) interface, a Long-Term Evolution (LTE) interface, or another cellular based interface, or a combination thereof. Network channel 382 can be connected to an external network resource (not illustrated). The network resource can include another information handling system, a data storage system, another network, a grid management system, another suitable resource, or a combination thereof.

BMC 390 is connected to multiple elements of information handling system 300 via one or more management interface 392 to provide out-of-band monitoring, maintenance, and control of the elements of the information handling system. As such, BMC 390 represents a processing device different from processor 302 and processor 304, which provides various management functions for information handling system 300. For example, BMC 390 may be responsible for power management, cooling management, and the like. The term BMC is often used in the context of server systems, while in a consumer-level device, a BMC may be referred to as an embedded controller (EC). A BMC included in a data storage system can be referred to as a storage enclosure processor. A BMC included at a chassis of a blade server can be referred to as a chassis management controller and embedded controllers included at the blades of the blade server can be referred to as blade management controllers. Capabilities and functions provided by BMC 390 can vary considerably based on the type of information handling system. BMC 390 can operate in accordance with an Intelligent Platform Management Interface (IPMI). Examples of BMC 390 include an Integrated Dell^{®} Remote Access Controller (iDRAC).

Management interface 392 represents one or more out-of-band communication interfaces between BMC 390 and the elements of information handling system 300 and can include an Inter-Integrated Circuit (I2C) bus, a SMBUS, a Power Management Bus (PMBUS), a Low Pin Count (LPC) interface, a serial bus such as a Universal Serial Bus (USB) or a Serial Peripheral Interface (SPI), a network interface such as an Ethernet interface, a high-speed serial data link such as a PCIe interface, a Network Controller Sideband Interface (NC-SI), or the like. As used herein, out-of-band access refers to operations performed apart from a BIOS/operating system execution environment on information handling system 300, that is apart from the execution of code by processors 302 and 304 and procedures that are implemented on the information handling system in response to the executed code.

BMC 390 operates to monitor and maintain system firmware, such as code stored in BIOS/EFI module 342, option ROMs for graphics adapter 330, disk controller 350, add-on resource 374, network interface 380, or other elements of information handling system 300, as needed or desired. In particular, BMC 390 includes a network interface 394 that can be connected to a remote management system to receive firmware updates, as needed or desired. Here, BMC 390 receives the firmware updates, stores the updates to a data storage device associated with the BMC, and transfers the firmware updates to NVRAM 340 of the device or system that is the subject of the firmware update, thereby replacing the currently operating firmware associated with the device or system, and reboots information handling system, whereupon the device or system utilizes the updated firmware image.

BMC 390 utilizes various protocols and application programming interfaces (APIs) to direct and control the processes for monitoring and maintaining the system firmware. An example of a protocol or API for monitoring and maintaining the system firmware includes a graphical user interface (GUI) associated with BMC 390, an interface defined by the Distributed Management Taskforce (DMTF) (such as a Web Services Management (WSMan) interface, a Management Component Transport Protocol (MCTP) or, a Redfish^{®} interface), various vendor defined interfaces (such as a Dell EMC Remote Access Controller Administrator (RACADM) utility, a Dell EMC OpenManage Enterprise, a Dell EMC OpenManage Server Administrator (OMSA) utility, a Dell EMC OpenManage Storage Services (OMSS) utility, or a Dell EMC OpenManage Deployment Toolkit (DTK) suite), a BIOS setup utility such as invoked by an “F2” boot option, or another protocol or API, as needed or desired.

In a particular embodiment, BMC 390 is included on a main circuit board (such as a baseboard, a motherboard, or any combination thereof) of information handling system 300 or is integrated onto another element of the information handling system such as chipset 310, or another suitable element, as needed or desired. As such, BMC 390 can be part of an integrated circuit or a chipset within information handling system 300. An example of BMC 390 includes an iDRAC, or the like. BMC 390 may operate on a separate power plane from other resources in information handling system 300. Thus BMC 390 can communicate with the management system via network interface 394 while the resources of information handling system 300 are powered off. Here, information can be sent from the management system to BMC 390 and the information can be stored in a RAM or NVRAM associated with the BMC. Information stored in the RAM may be lost after power-down of the power plane for BMC 390, while information stored in the NVRAM may be saved through a power-down/power-up cycle of the power plane for the BMC.

Information handling system 300 can include additional components and additional buses, not shown for clarity. For example, information handling system 300 can include multiple processor cores, audio devices, and the like. While a particular arrangement of bus technologies and interconnections is illustrated for the purpose of an example, one of skill will appreciate that the techniques disclosed herein are applicable to other system architectures. Information handling system 300 can include multiple CPUs and redundant bus controllers. One or more components can be integrated together. Information handling system 300 can include additional buses and bus protocols, for example, I²C and the like. Additional components of information handling system 300 can include one or more storage devices that can store machine-executable code, one or more communications ports for communicating with external devices, and various input and output (I/O) devices, such as a keyboard, a mouse, and a video display.

For purposes of this disclosure, information handling system 300 can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smartphone, a tablet device or other consumer electronic device, a network server, a network storage device, a switch, a router, or another network communication device, or any other suitable device and may vary in size, shape, performance, functionality, and price. Further, information handling system 300 can include processing resources for executing machine-executable code, such as processor 302, a programmable logic array (PLA), an embedded device such as a System-on-a-Chip (SoC), or other control logic hardware. Information handling system 300 can also include one or more computer-readable media for storing machine-executable code, such as software or data.

Although FIG. 2 shows example blocks of method 200 in some implementations, method 200 may include additional blocks, fewer blocks, different blocks, or differently arranged blocks than those depicted in FIG. 2. Those skilled in the art will understand that the principles presented herein may be implemented in any suitably arranged processing system. Additionally, or alternatively, two or more of the blocks of method 200 may be performed in parallel.

In accordance with various embodiments of the present disclosure, the methods described herein may be implemented by software programs executable by a computer system. Further, in an exemplary, non-limited embodiment, implementations can include distributed processing, component/object distributed processing, and parallel processing. Alternatively, virtual computer system processing can be constructed to implement one or more of the methods or functionalities as described herein.

When referred to as a “device,” a “module,” a “unit,” a “controller,” or the like, the embodiments described herein can be configured as hardware. For example, a portion of an information handling system device may be hardware such as, for example, an integrated circuit (such as an ASIC, an FPGA, a structured ASIC, or a device embedded in a larger chip), a card (such as a Peripheral Component Interface (PCI) card, a PCI-express card, a Personal Computer Memory Card International Association (PCMCIA) card, or other such expansion card), or a system (such as a motherboard, a system-on-a-chip (SoC), or a stand-alone device).

The present disclosure contemplates a computer-readable medium that includes instructions or receives and executes instructions responsive to a propagated signal; so that a device connected to a network can communicate voice, video, or data over the network. Further, the instructions may be transmitted or received over the network via the network interface device.

While the computer-readable medium is shown to be a single medium, the term “computer-readable medium” includes a single medium or multiple media, such as a centralized or distributed database, and/or associated caches and servers that store one or more sets of instructions. The term “computer-readable medium” shall also include any medium that is capable of storing, encoding, or carrying a set of instructions for execution by a processor or that causes a computer system to perform any one or more of the methods or operations disclosed herein.

In a particular non-limiting, exemplary embodiment, the computer-readable medium can include a solid-state memory such as a memory card or other package that houses one or more non-volatile read-only memories. Further, the computer-readable medium can be a random-access memory or other volatile re-writable memory. Additionally, the computer-readable medium can include a magneto-optical or optical medium, such as a disk or tapes, or another storage device to store information received via carrier wave signals such as a signal communicated over a transmission medium. A digital file attachment to an e-mail or other self-contained information archive or set of archives may be considered a distribution medium that is equivalent to a tangible storage medium. Accordingly, the disclosure is considered to include any one or more of a computer-readable medium or a distribution medium and other equivalents and successor media, in which data or instructions may be stored.

Although only a few exemplary embodiments have been described in detail above, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents but also equivalent structures.

What is claimed is:

1. A method comprising:
monitoring, by a processor, an information handling system to detect whether the information handling system is transitioning to a sleep state;
if the information handling system is transitioning to the sleep state, then analyzing at least one metric associated with a battery of the information handling system; and
if the metric exceeds a threshold limit, then performing at least one action associated with the battery based on the metric.

2. The method of claim 1, further comprising switching a battery management unit into a maintenance mode.

3. The method of claim 1, wherein the analyzing of at least one metric associated with the battery of the information handling system includes determining whether a rate of discharge of the battery of the information handling system is within the threshold limit.

4. The method of claim 1, wherein the action includes performing diagnostics.

5. The method of claim 1, wherein the action includes recalibrating the battery.

6. The method of claim 1, wherein the action includes updating a set of configuration settings.

7. The method of claim 1, wherein the at least one action may be performed based on contextual data.

8. The method of claim 1, further comprising pushing contextual data into a battery management unit.

9. The method of claim 1, further comprising storing a binary large object that includes a set of configuration settings in a partition of a flash memory associated with the battery.

10. The method of claim 7, further comprising storing a firmware image in a partition of a flash memory associated with the battery.

11. An information handling system, comprising:
a processor; and
a memory coupled to the processor, the memory having program instructions stored thereon that upon execution cause the processor to:
monitor the information handling system to detect whether the information handling system is transitioning to a sleep state;
if the information handling system is transitioning to the sleep state, then analyze at least one metric associated with a battery of the information handling system; and
if the metric exceeds a threshold limit, then perform at least one action associated with the battery based on the metric.

12. The information handling system of claim 11, wherein the program instructions further cause the processor to switch a battery management unit into a maintenance mode.

13. The information handling system of claim 11, wherein the analyzing of at least one metric associated with the battery of the information handling system includes determining whether a rate of discharge of the battery of the information handling system exceeds the threshold limit.

14. The information handling system of claim 11, wherein the action includes performing diagnostics.

15. The information handling system of claim 11, wherein the action includes recalibrating the battery.

16. A non-transitory computer-readable medium to store instructions that are executable to perform operations comprising:
monitoring an information handling system, by a processor, to detect whether the information handling system is transitioning to a modern standby state;
if the information handling system is transitioning to the modern standby state, then analyzing at least one metric associated with a battery of the information handling system; and
if the metric exceeds a threshold limit, then performing at least one action based on the metric.

17. The non-transitory computer-readable medium of claim 16, whether the operations further comprise switching a battery management unit into a maintenance mode.

18. The non-transitory computer-readable medium of claim 16, wherein the analyzing of at least one metric associated with the battery of the information handling system includes determining whether a rate of discharge of the battery of the information handling system exceeds the threshold limit.

19. The non-transitory computer-readable medium of claim 16, wherein the action includes performing diagnostics.

20. The non-transitory computer-readable medium of claim 16, wherein the action includes recalibrating the battery.
